(19) United States
(12) Patent Application Publication
(10) Pub. No.: US 2024/0177913 A1
(43) Pub. Date: May 30, 2024

(54) ELECTRONIC COMPONENT

(71) Applicant: DIAMOND&ZEBRA ELECTRIC MFG. CO., LTD., Osaka (JP)

(72) Inventor: Takashi IKEBE, Osaka (JP)

(73) Assignee: DIAMOND&ZEBRA ELECTRIC MFG. CO., LTD., Osaka (JP)

(21) Appl. No.: 18/386,026

(22) Filed: Nov. 1, 2023

(30) Foreign Application Priority Data
Nov. 29, 2022 (JP) 2022-189803

(51) Int. Cl. H01F 27/22; H01F 27/02; H01F 27/28

(52) U.S. Cl. CPC H01F 27/22; H01F 27/02; H01F 27/28

(57) ABSTRACT

An electronic component includes: a heat generator; a case containing therein a part or whole of the heat generator, the case including a body and a bottom; and a filler filling a gap between the heat generator and the case. The body is electrically insulating, and the bottom is electrically insulating and thermally conductive. Preferably, the bottom includes a heat dissipation sheet. The bottom may be made of a ceramic. Preferably, the body includes a main portion and a flange portion located at an end of the main portion that faces the bottom, the flange portion projecting outward or inward from the main portion.

### CROSS-REFERENCE TO RELATED APPLICATION

This application claims priority on and the benefit of Patent Application No. 2022-189803 filed in JAPAN on Nov. 29, 2022. The entire disclosures of this Japanese Patent Application are hereby incorporated by reference.

### BACKGROUND OF THE INVENTION

### Field of the Invention

The present specification discloses an electronic component.

### Description of the Related Art

Some electronic devices employ an electronic component such as a toroidal coil or transformer that generates a large amount of heat. Such a heat-generating electronic component often has a structure where a case made of a resin composition or metal contains therein a “heat generator” that actually generates heat. An example of the heat-generating electronic component is reported in Japanese Laid-Open Patent Application Publication No. 2011-210791.

Forming the case using a metal is expected to result in high heat dissipation performance. However, the case and the heat generator need to be at a sufficient distance from each other to ensure the electrical insulation between the case and the heat generator. This is an obstacle to size reduction of the electronic component. Forming the case using a resin composition ensures the electrical insulation between the case and the heat generator, but is disadvantageous in achieving high heat dissipation performance. An electronic component having a reduced size and high heat dissipation performance is desired.

The present inventors aim to provide an electronic component having a reduced size and high heat dissipation performance.

### SUMMARY OF THE INVENTION

An electronic component includes: a heat generator; a case containing therein a part or whole of the heat generator, the case including a body and a bottom; and a filler filling a gap between the heat generator and the case. The body is electrically insulating, and the bottom is electrically insulating and thermally conductive. In the electronic component, the body and the bottom of the case are electrically insulating. Thus, the distance between the case and the heat generator can be reduced. The electronic component has a reduced size. Additionally, the bottom of the case is thermally conductive. The bottom contributes to effective heat dissipation. For example, the electronic component may be mounted into an electronic device such that the bottom is in contact with a component such as a housing or heat dissipator which exhibits a high heat dissipation effect, and this allows for effective dissipation of heat emitted from the heat generator. The electronic component has high heat dissipation performance.

### BRIEF DESCRIPTION OF THE DRAWINGS

FIG. 1 is a perspective view showing an electronic component according to one embodiment.

FIG. 2 is an exploded perspective view of the electronic component of FIG. 1.

FIG. 3 is a cross-sectional view of the electronic component taken along the line III-III of FIG. 1.

FIG. 4 is a cross-sectional view showing a case of the electronic component of FIG. 1.

FIG. 5 is a cross-sectional view showing the electronic component of FIG. 1 as mounted in an electronic device.

FIG. 6 is a cross-sectional view showing an electronic component according to another embodiment.

### DESCRIPTION OF THE PREFERRED EMBODIMENTS

The following will describe in detail preferred embodiments with appropriate reference to the drawings.

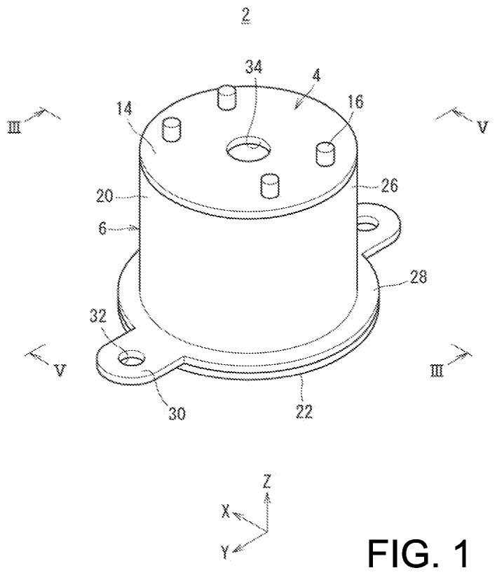

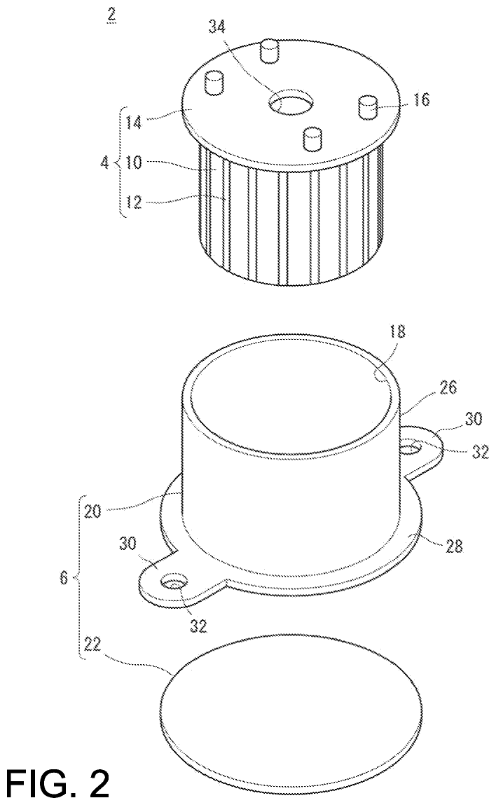

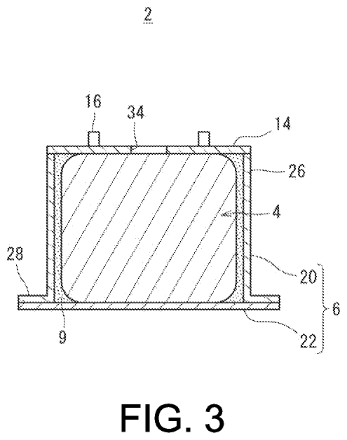

FIG. 1 is a perspective view showing an electronic component 2 according to one embodiment. In FIG. 1, the arrow X represents the forward direction with respect to the electronic component 2. The opposite direction is the backward direction. The arrow Y represents the rightward direction with respect to the electronic component 2. The opposite direction is the leftward direction. The arrow Z represents the upward direction with respect to the electronic component 2. The opposite direction is the downward direction. FIG. 2 is an exploded perspective view of the electronic component 2 of FIG. 1. FIG. 3 is a cross-sectional view taken along the line III-III of FIG. 1. The electronic component 2 includes a toroidal coil 4 and a case 6. As shown in FIG. 3, the electronic component 2 includes a filler 9 in a gap between the toroidal coil 4 and the case 6.

As shown in FIG. 2, the toroidal coil 4 includes a core 10, a wire 12, and a top plate 14. The core 10 is annular although the core 10 is not seen in its entirety in the figure. The core 10 is made of a magnetic material whose surface is covered with a resin composition. Preferred examples of the magnetic material include ferrite, dust, and silicon steel. The wire 12 is helically wound around the outer circumference of the core 10. The wire 12 is typically made of copper. In FIG. 3, the core 10 and the wire 12 are depicted in a simplified manner. In FIG. 3, the core 10 and the wire 12 are collectively depicted as one cross-section.

The top plate 14 is located on the upper surface of the core 10 (the surface that faces upward when the axial direction of the annular core 10 is defined as the up-down direction of the core 10). At the center of the top plate 14 there is a hole 34. A plurality of terminals 16 are located on the upper surface of the top plate 14. Although not shown, the terminals 16 are electrically connected to the wire 12. Electricity is externally applied to the wire 12 through the terminals 16. Upon application of electricity to the wire 12, the toroidal coil 4 generates heat. The toroidal coil 4 is a heat generator 4.

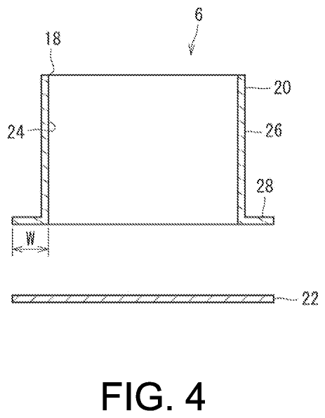

The case 6 includes an internal space. The case 6 contains a part or whole of the toroidal coil 4 in the space. The case 6 includes an opening 18 at its upper surface. As shown in FIGS. 2 and 3, the case 6 includes a body 20 and a bottom 22. FIG. 4 is a cross-sectional view showing the case 6. FIGS. 2 and 4 show the body 20 and the bottom 22 as separated from each other.

As shown in FIG. 4, the body 20 includes a hole 24 extending through the interior of the body 20 in the up-down direction. The body 20 is electrically insulating. In this embodiment, the body 20 is made of a resin composition. Preferred examples of the material of the body 20 include PBT (polybutylene terephthalate), PPS (polyphenylene sulfide), and PET (polyethylene terephthalate). In the present specification, the statement that a material is “electrically insulating” means that the electrical conductivity of the material is 10⁻⁶ S/m or less. “S” denotes siemens which is the reciprocal of resistance “Ω (ohm)”, and “m” denotes distance (meter).

The body 20 includes a main portion 26 and a flange portion 28. The main portion 26 is tubular. The flange portion 28 is located at the lower end of the main portion 26 (the end that faces the bottom 22). The flange portion 28 extends in the circumferential direction along the lower end of the main portion 26. The flange portion 28 is ring-shaped. In this embodiment, the flange portion 28 projects outward from the main portion 26 in the radial direction of the case 6. As shown in FIG. 2, the flange portion 28 includes a protrusion 30 that projects outward in the radial direction. In this embodiment, there are two such protrusions 30. Each of the protrusions 30 includes an attachment hole 32. The main portion 26 and the flange portion 28 are integrally formed. The main portion 26 and the flange portion 28 may be separately formed.

The bottom 22 is plate-shaped. As shown in FIG. 3, the bottom 22 is in contact with the flange portion 28. In this embodiment, the entire lower surface of the flange portion 28 is in contact with the bottom 22. The bottom 22 covers the entire opening of the hole 24 of the body 20. The bottom 22 is fixed to the flange portion 28. In this embodiment, the bottom 22 is fixed to the flange portion 28 by means of an adhesive. The bottom 22 may be made of a material having adhesive properties, by which the bottom 22 and the flange portion 28 may be fixed together.

The bottom 22 is electrically insulating and thermally conductive. In this embodiment, the bottom 22 consists of a heat dissipation sheet that is electrically insulating. The bottom 22 may be formed from another material that is electrically insulating and thermally conductive. In the present specification, the statement that a material is “thermally conductive” means that the thermal conductivity of the material is 0.5 W/m·K or more. “W” denotes electrical power (watt), “m” denotes distance (meter), and “K” denotes temperature (kelvin).

The filler 9 fills the gap between the toroidal coil 4 and the case 6. In the embodiment of FIG. 3, the filler 9 is located between the top plate 14 of the toroidal coil 4 and the case 6. The filler 9 is electrically insulating. In this embodiment, the filler 9 is made of a thermosetting resin. A resin that cures at ordinary temperature may be used as the filler 9. Preferably, a resin having high thermal conductivity is selected. The resin selected as the material of the filler 9 has low viscosity to completely fill the entire gap inside the case 6. Preferred examples of the filler 9 include epoxy resins.

In production of the electronic component 2, the body 20 of the case 6, a heat dissipation sheet for use as the bottom 22, and the toroidal coil 4 are prepared. The main portion 26 and the flange portion 28 of the body 20 are integrally formed. The bottom 22 is bonded to the flange portion 28 by means of an adhesive. Thus, the case 6 is formed. The toroidal coil 4 is inserted into the case 6. The toroidal coil 4 is contained in the case 6. A liquid thermosetting resin is poured into the case 6 through the hole 34 of the top plate 14 of the toroidal coil 4. The thermosetting resin fills the gap between the case 6 and the toroidal coil 4. The thermosetting resin is heated and cured. Thus, the filler 9 is formed. In this manner, the electronic component 2 is obtained.

The body 20 and the bottom 22 need not be bonded together. For example, the thermosetting resin may be poured into the case 6 with the body 20 pressed against the bottom 22. In this case, heating and curing of the thermosetting resin result in the body 20 and the bottom 22 being fixed to each other.

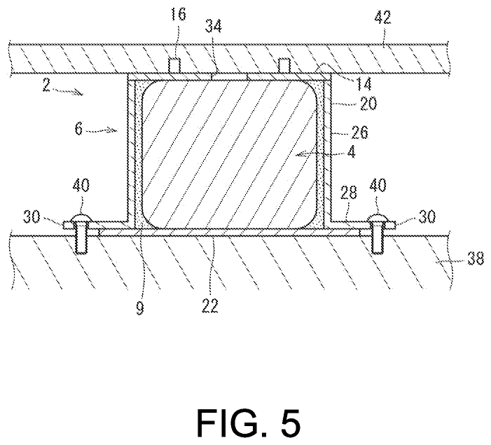

The electronic component 2 obtained is mounted into an electronic device. FIG. 5 shows an example of the electronic component 2 as mounted in the electronic device. The electronic component 2 of FIG. 5 is shown as a cross-section taken along the line V-V of FIG. 1. This cross-sectional view, unlike the cross-sectional view of FIG. 3, shows a cross-section taken at a site where there are the protrusions 30 of the flange portion 28. In this embodiment, the electronic component 2 is located on a heat dissipator 38 of the electronic device. The electronic component 2 is placed such that the bottom 22 is in contact with the heat dissipator 38. The electronic component 2 is fixed to the heat dissipator 38 by inserting screws 40 into the heat dissipator 38 through the attachment holes 32 of the bottom 22. The electronic component 2 may be located on a housing of the electronic device. The electronic component 2 may be located on another component of the electronic device that exhibits a high heat dissipation effect.

In the embodiment of FIG. 5, a circuit board 42 is located above the electronic component 2. The terminals 16 of the toroidal coil 4 connect with given terminals of the circuit board 42. Thus, electricity is applied from the circuit board 42 to the toroidal coil 4, bringing the electronic component 2 into operation.

The following will describe the advantageous effects of the present embodiment.

In the electronic component 2, both the body 20 and the bottom 22 of the case 6 are electrically insulating. This prevents electrical short circuit between the toroidal coil 4 which is a heat generator 4 and the case 6. In the electronic component 2, the distance between the case 6 and the heat generator 4 can be reduced. The electronic component 2 has a reduced size.

In terms of achieving good electrical insulation, the electrical conductivity of the case 6 is more preferably 10⁻⁸ S/m or less, even more preferably 10⁻¹⁰ S/m or less, and yet even more preferably 10⁻¹² S/m or less.

In the electronic component 2, the bottom 22 of the case 6 is formed as a heat dissipation sheet. Heat emitted from the heat generator 4 can be effectively discharged outside through the bottom 22. For example, the electronic component 2 may be mounted into the electronic device such that the bottom 22 is in contact with a component such as the housing or heat dissipator 38 which exhibits a high heat dissipation effect, and this allows for more effective dissipation of heat emitted from the heat generator 4.

In terms of achieving high heat dissipation performance of the electronic component 2, the thermal conductivity of the bottom 22 is more preferably 1.0 W/m·K or more, even more preferably 3.0 W/m·K or more, and yet even more preferably 10 W/m·K or more.

If the case 6 is made of an electrically conductive material such as a metal, ensuring electrical insulation between the electronic component 2 and another component of the electronic device requires an electrically insulating material interposed between the case 6 and the other component. For example, a heat dissipation sheet needs to be disposed between the case 6 and the housing or a cooler. Since the case 6 of the electronic component 2 is electrically insulating, there is no need to use any electrically insulating material for electrically insulating the electronic component 2 from the other component. The use of the electronic component 2 prevents an increase in the number of components of the electronic device.

In this embodiment, the body 20 of the case 6 includes the flange portion 28 projecting outward from the main portion 26 in the radial direction. The bottom 22 is in contact with the flange portion 28. Thanks to the flange portion 28, the area of contact between the body 20 and the bottom 22 can be greater than when the body 20 is devoid of the flange portion 28. This can effectively prevent a thermosetting resin from leaking out of the case 6 when the thermosetting resin is poured into the case 6 during production.

In FIG. 4, the reference sign W represents the width of the flange portion 28. The width W is measured in the radial direction. In this embodiment, the width W of the flange portion 28 is equal to or greater than the creepage distance from the body 20 of the electronic component 2. This can ensure reliable electrical insulation between the electronic component 2 and another component.

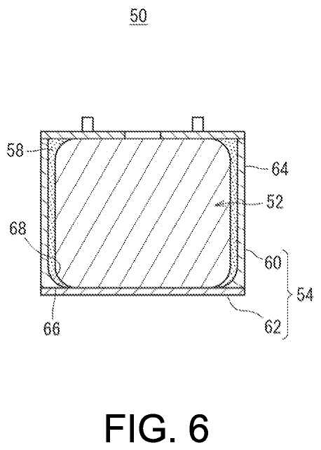

FIG. 6 is a cross-sectional view showing an electronic component 50 according to another embodiment. The electronic component 50 includes a toroidal coil 52 and a case 54. The electronic component 50 includes a filler 58 in a gap between the toroidal coil 52 and the case 54. The toroidal coil 52 and the filler 58 of the electronic component 50 are respectively the same as the toroidal coil 4 and the filler 9 of the electronic component 2 of FIGS. 1 to 3.

The case 54 includes an internal space. The case 54 contains the toroidal coil 52 in the space. The case 54 includes an opening at its upper surface. The case 54 includes a body 60 and a bottom 62. The body 60 includes a hole extending through the interior of the body 60 in the up-down direction. The body 60 is electrically insulating. In this embodiment, the body 60 is made of a resin composition.

The body 60 includes a main portion 64 and a flange portion 66. The main portion 64 is tubular. The flange portion 66 is located at the lower end of the main portion 64 (the end that faces the bottom 62). The flange portion 66 extends along the lower end of the main portion 64. The flange portion 66 is ring-shaped. In this embodiment, as shown in FIG. 6, the flange portion 66 projects inward from the main portion 64. Within the case 54, a corner between the main portion 64 and the flange portion 66 is shaped to have a rounded contour 68. Although not shown, the flange portion 66 includes a protrusion projecting outward in the radial direction. In this embodiment, there are two such protrusions. Each of the protrusion includes an attachment hole. The main portion 64 and the flange portion 66 are integrally formed. The main portion 64 and the flange portion 66 may be separately formed.

The bottom 62 is plate-shaped. As shown in FIG. 6, the bottom 62 is in contact with the flange portion 66. In this embodiment, the entire lower surface of the flange portion 66 is in contact with the bottom 62. The bottom 62 covers the entire opening of the hole of the body 60. The bottom 62 is fixed to the flange portion 66. In this embodiment, the bottom 62 is fixed to the flange portion 66 by means of an adhesive. The bottom 62 may be made of a material having adhesive properties, by which the bottom 62 and the flange portion 66 may be fixed together. The bottom 62 is electrically insulating and thermally conductive. In this embodiment, the bottom 62 consists of a heat dissipation sheet that is electrically insulating. The bottom 62 may be formed from another material that is electrically insulating and thermally conductive.

In the electronic component 50, both the body 60 and the bottom 62 of the case 54 are electrically insulating. This prevents electrical short circuit between the toroidal coil 52 which is a heat generator 52 and the case 54. In the electronic component 50, the distance between the case 54 and the heat generator 52 can be reduced. The electronic component 50 has a reduced size. Additionally, in the electronic component 50, the bottom 62 of the case 54 is formed as a heat dissipation sheet. Heat emitted from the heat generator 52 can be effectively discharged outside through the bottom 62. For example, the electronic component 50 may be mounted into an electronic device such that the bottom 62 is in contact with a housing or heat dissipator of the electronic device, and this allows for more effective dissipation of heat emitted from the heat generator 52.

In this embodiment, the body 60 of the case 54 includes the flange portion 66 projecting inward from main portion 64 in the radial direction. The bottom 62 is in contact with the flange portion 66. Thanks to the flange portion 66, the area of contact between the body 60 and the bottom 62 can be greater than when the body 60 is devoid of the flange portion 66. This can effectively prevent a thermosetting resin from leaking out of the case 54 when the thermosetting resin is poured into the case 54 during production.

In this embodiment, within the case 54, a corner between the main portion 64 and the flange portion 66 is shaped to have the rounded contour 68. In many instances, the heat generator 52 contained in the case 54 is shaped to have the rounded contour 68, as is typical with a coil. For example, as shown in FIG. 6, a corner between the surface of the toroidal coil 52 that faces the bottom 62 and the surface of the toroidal coil 52 that faces the body 60 is shaped to have a rounded contour. Even though the corner between the main portion 64 and the flange portion 66 is shaped to have the rounded contour 68, neither the main portion 64 nor the flange portion 66 is in contact with the heat generator 52. Since the corner between the main portion 64 and the flange portion 66 is shaped to have the rounded contour 68, the gap between the heat generator 52 and the case 54 can be reduced. This can reduce the required amount of the filler 58.

In terms of further reducing the gap between the heat generator 52 and the case 54, the rounded contour 68 preferably conforms to the rounded contour of the corner between the surfaces of the toroidal coil 52 that respectively face the bottom 62 and the body 60.

An electronic component according to yet another embodiment has the same structure as the electronic component 2 as shown in FIGS. 1 to 3. The electronic component of this embodiment differs from the electronic component 2 of FIG. 1 in the material of the bottom. In this electronic component, the bottom is made of a ceramic. The bottom is electrically insulating and thermally conductive. Preferred examples of the ceramic include alumina, zirconia, and silicon nitride. The electronic component is the same as the electronic component 2 of FIG. 1, except that the material of the bottom is a ceramic.

The electronic component is mounted into an electronic device. The placement of the electronic component is done, for example, such that the bottom is in contact with a housing or heat dissipator of the electronic device. The electronic component is fixed by inserting screws into the housing or heat dissipator through attachment holes of the bottom. In this embodiment, a heat dissipation sheet may be disposed between the bottom of the electronic component and the housing or heat dissipator. Heat dissipation grease may be interposed between the bottom and the housing or heat dissipator.

In the electronic component, both the body and the bottom of the case are electrically insulating. This prevents electrical short circuit between the toroidal coil which is a heat generator and the case. In the electronic component, the distance between the case and the heat generator can be reduced. The electronic component has a reduced size.

In the electronic component, the bottom of the case is made of a ceramic. Heat emitted from the heat generator can be effectively discharged outside through the bottom. For example, the electronic component may be mounted into the electronic device such that the bottom is in contact with a component such as the housing or heat dissipator which exhibits a high heat dissipation effect, and this allows for more effective dissipation of heat emitted from the heat generator.

In the embodiments described above, the flange portion of the body projects outward or inward from the main portion. The flange portion may project both outward and inward from the main portion. The body may include no flange portion.

In the embodiments described above, the toroidal coil is contained as a heat generator in the case. The heat generator is not limited to toroidal coils. The heat generator may be a reactor, transformer, or resistor. The heat generator may be any other element.

As described above, the electronic components have a reduced size and high heat dissipation performance. This demonstrates the superiority of the described embodiments.

### [Disclosed Items]

The following items are disclosures of preferred embodiments.

[Item 1]

An electronic component including:
a heat generator;
a case containing therein a part or whole of the heat generator, the case including a body and a bottom; and
a filler filling a gap between the heat generator and the case, wherein
the body is electrically insulating, and
the bottom is electrically insulating and thermally conductive.

[Item 2]

The electronic component according to Item 1, wherein the bottom includes a heat dissipation sheet.

[Item 3]

The electronic component according to item 1, wherein the bottom is made of a ceramic.

[Item 4]

The electronic component according to any one of items 1 to 3, wherein the body includes a main portion and a flange portion located at an end of the main portion that faces the bottom, the flange portion projecting outward or inward from the main portion.

[Item 5]

The electronic component according to item 4, wherein
the flange portion projects inward from the main portion, and
within the case, a corner between the main portion and the flange portion is shaped to have a rounded contour.

[Item 6]

The electronic component according to any one of items 1 to 5, wherein the heat generator includes a coil.

The electronic component as described above is applicable to various electronic devices.

The foregoing description is given for illustrative purposes, and various modifications can be made without departing from the principles of the present invention.

What is claimed is:

1. An electronic component comprising:
a heat generator;
a case containing therein a part or whole of the heat generator, the case including a body and a bottom; and
a filler filling a gap between the heat generator and the case, wherein
the body is electrically insulating, and
the bottom is electrically insulating and thermally conductive.

2. The electronic component according to claim 1, wherein the bottom includes a heat dissipation sheet.

3. The electronic component according to claim 1, wherein the bottom is made of a ceramic.

4. The electronic component according to claim 1, wherein the body includes a main portion and a flange portion located at an end of the main portion that faces the bottom, the flange portion projecting outward or inward from the main portion.

5. The electronic component according to claim 4, wherein the flange portion projects inward from the main portion, and
within the case, a corner between the main portion and the flange portion is shaped to have a rounded contour.

6. The electronic component according to claim 1, wherein the heat generator includes a coil.
